(19) United States
(12) Patent Application Publication
(10) Pub. No.: US 2010/0224951 A1
(43) Pub. Date: Sep. 9, 2010

(54) Solid-state imaging device, method for producing the same, and electronic apparatus

(75) Inventor: Yutaka Nishimura, Kanagawa (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 12/660,579

(22) Filed: Mar. 1, 2010

(30) Foreign Application Priority Data
Mar. 9, 2009 (JP) P2009-055253

(51) Int. Cl. H01L 23/48; H01L 21/768

(52) U.S. Cl. 257/459; 438/98; 257/E21.585; 257/E23.011

(57) ABSTRACT

A solid-state imaging device includes: a peripheral circuit element formed on a semiconductor substrate having an image sensing area where an image sensing element that captures an image of an object is provided and a peripheral area located on the periphery of the image sensing area, the peripheral circuit element being in the peripheral area; a plurality of insulation films formed to cover at least the peripheral circuit element; and a contact plug formed in a contact hole through the plurality of insulation films and above the peripheral circuit element in such a manner that the contact plug is electrically connected to the peripheral circuit element; the plurality of insulation films including a first insulation film, and a second insulation film formed to cover the first insulation film, the contact hole being formed by etching the second insulation film so as to remove a portion thereof where the contact hole is to be formed, and then etching the first insulation film so as to remove a portion thereof where the contact hole is to be formed, the first insulation film being formed to serve as an etching stopper layer during etching of the second insulation film, the first insulation film also being formed to cover a portion where the contact hole is to be formed above the peripheral circuit element, with portions other than the portion where the contact hole is to be formed above the peripheral circuit element being exposed.

### CROSS-REFERENCE TO RELATED APPLICATION

The present application claims priority from Japanese Patent Application No. JP 2009-055253 filed in the Japanese Patent Office on Mar. 9, 2009, the entire content of which is incorporated herein by reference.

### BACKGROUND OF THE INVENTION

1. Field of the Invention

The present invention relates to a solid-state imaging device, a method for producing the same, and an electronic apparatus. In particular, the invention relates to a solid-state imaging device having, in the image sensing area thereof, an image sensing element that captures an image of an object; a method for producing the same; and an electronic apparatus.

2. Description of the Related Art

An electronic apparatus such as a digital video camera or a digital still camera includes a solid-state imaging device. An example of such a solid-state imaging device included is a CMOS (Complementary Metal Oxide Semiconductor) image sensor.

As a solid-state imaging device, a CMOS image sensor provides the following advantages:

A CMOS logic LSI process can be applied.

Peripheral circuits can be formed on a chip.

Low-voltage driving is possible.

Power consumption is low.

In a CMOS image sensor, a plurality of image sensing elements that capture an image of an object are formed as pixels. The plurality of pixels each have a photoelectric converter so as to receive incident light and photoelectrically convert the received light, thereby generating signal charges. For example, a photodiode is formed as such a photoelectric converter. Further, an interconnect layer with a multilayer structure is provided to electrically connect the elements (see, e.g., JP-A-2005-278135 and JP-A-2005-323331).

The interconnect layer with a multilayer structure has a contact plug formed in the following manner: specifically, an insulation film is anisotropically etched to form a contact hole, and the contact hole is then filled with an electrically conductive material to provide the contact plug.

In such anisotropic etching, the etch selectivity is low between insulation films (SiO₂-based films), element electrodes (polysilicon, tungsten), and the silicon substrate. Therefore, a SiN film is provided as an etching stopper layer on the electrodes (polysilicon, tungsten) and also on the silicon substrate. After etching to remove the insulation layer on the etching stopper layer, further etching is performed to remove the etching stopper layer. That is, the etching is completed in two steps (see, e.g., JP-A-2000-243832).

With respect to a CMOS image sensor, for the purpose of improving the image quality of a captured image, a method for suppressing dark current has been proposed.

In order to prevent dark current, hydrogenation is performed to terminate the silicon dangling bonds of the silicon semiconductor substrate, thereby reducing the interface state (see, e.g., JP-A-2004-165236 and JP-A-2003-229556).

### SUMMARY OF THE INVENTION

In a CMOS image sensor, the peripheral circuits may cause noise, reducing the image quality of a captured image.

In particular, in an ADC (analog-to-digital-conversion circuit) that converts analog signals read out from image sensing elements row by row into digital signals, a comparator that compares such an analog signal with a reference signal has been found to be a random noise source.

In addition, a DAC (digital-to-analog converter circuit) that generates the reference signal has also been found to be a random noise source.

In preventing the generation of noise, it is effective to subject elements forming the peripheral circuits to the above-mentioned hydrogenation.

In the hydrogenation, however, above a peripheral circuit, an etching stopper layer for use in etching to form contact holes may interfere with the permeation of hydrogen, making it difficult to prevent the generation of noise. For example, an LP-SiN film formed by low-pressure CVD hardly allows the permeation of hydrogen, possibly causing the problem.

Further, above a peripheral circuit, metal interconnects are provided as a light-shielding film. Like the etching stopper layer, the metal interconnects may interfere with the permeation of hydrogen, making it difficult to prevent the generation of noise.

The image quality of a captured image is thus occasionally reduced due to peripheral circuits.

The invention thus provides a solid-state imaging device capable of improving the image quality of a captured image, a method for producing the same, and an electronic apparatus.

A method for forming a solid-state imaging device according to one embodiment of the invention includes: an element-forming process of forming a peripheral circuit element on a semiconductor substrate having an image sensing area where an image sensing element that captures an image of an object is provided and a peripheral area located on the periphery of the image sensing area, the peripheral circuit element being in the peripheral area; an insulation-film-forming process of forming a plurality of insulation films so as to cover at least the peripheral circuit element; a contact-hole-forming process of forming a contact hole through the plurality of insulation films and above the peripheral circuit element, the contact hole receiving a contact plug that is electrically connected to the peripheral circuit element; and a hydrogenation process of subjecting the semiconductor substrate having the plurality of insulation films to hydrogenation. The insulation-film-forming process includes: a first-insulation-film-forming step of forming as one of the insulation films a first insulation film; and a second-insulation-film-forming step of forming as one of the insulation films a second insulation film to cover the first insulation film. The contact-hole-forming process includes: a first etching step of etching the second insulation film so as to remove a portion thereof where the contact hole is to be formed; and a second etching step of, after the first etching step, etching the first insulation film so as to remove a portion thereof where the contact hole is to be formed. The first-insulation-film-forming step includes: forming the first insulation film to serve as an etching stopper layer during etching in the first etching step; and also forming the first insulation film to cover a portion where the contact hole is to be formed above the peripheral circuit element, with portions other than the portion where the contact hole is to be formed above the peripheral circuit element being exposed.

A solid-state imaging device according to an embodiment of the invention includes: a peripheral circuit element formed on a semiconductor substrate having an image sensing area where an image sensing element that captures an image of an object is provided and a peripheral area located on the periphery of the image sensing area, the peripheral circuit element being in the peripheral area; a plurality of insulation films formed to cover at least the peripheral circuit element; and a contact plug formed in a contact hole through the plurality of insulation films and above the peripheral circuit element in such a manner that the contact plug is electrically connected to the peripheral circuit element. The plurality of insulation films include a first insulation film and a second insulation film formed to cover the first insulation film. The contact hole is formed by etching the second insulation film so as to remove a portion thereof where the contact hole is to be formed, and then etching the first insulation film so as to remove a portion thereof where the contact hole is to be formed. The first insulation film is formed to serve as an etching stopper layer during etching of the second insulation film, and is also formed to cover a portion where the contact hole is to be formed above the peripheral circuit element, with portions other than the portion where the contact hole is to be formed above the peripheral circuit element being exposed.

An electronic apparatus according to an embodiment of the invention includes: a peripheral circuit element formed on a semiconductor substrate having an image sensing area where an image sensing element that captures an image of an object is provided and a peripheral area located on the periphery of the image sensing area, the peripheral circuit element being in the peripheral area; a plurality of insulation films formed to cover at least the peripheral circuit element; and a contact plug formed in a contact hole through the plurality of insulation films and above the peripheral circuit element in such a manner that the contact plug is electrically connected to the peripheral circuit element. The plurality of insulation films include a first insulation film and a second insulation film formed to cover the first insulation film. The contact hole is formed by etching the second insulation film so as to remove a portion thereof where the contact hole is to be formed, and then etching the first insulation film so as to remove a portion thereof where the contact hole is to be formed. The first insulation film is formed to serve as an etching stopper layer during etching of the second insulation film, and is also formed to cover a portion where the contact hole is to be formed above the peripheral circuit element, with portions other than the portion where the contact hole is to be formed above the peripheral circuit element being exposed.

According to an embodiment of the invention, the first insulation film is formed to serve as an etching stopper layer during etching to form contact holes in the second insulation film. Here, prior to the etching, the first insulation film is patterned to cover a portion where a contact hole is to be formed above a peripheral circuit element forming a peripheral circuit, with other portions being exposed. Accordingly, at the time of hydrogenation, the first insulation film (etching stopper layer) that interferes with the permeation of hydrogen is not formed at portions other than the portion where the contact hole is to be formed above the peripheral circuit element. As a result, the peripheral circuit element suitably receives the effect of hydrogenation.

According to some embodiments of the invention, a solid-state imaging device capable of improving the image quality of a captured image, a method for producing the same, and an electronic apparatus can be provided.

### BRIEF DESCRIPTION OF THE DRAWINGS

FIG. 1 is a block diagram showing the configuration of a camera 40 according to an embodiment of the invention.

FIG. 2 schematically shows the configuration of a solid-state imaging device 1 according to an embodiment of the invention.

FIG. 3 is a circuit diagram showing the main part of a pixel P provided in an image sensing area PA according to an embodiment of the invention.

FIG. 4 shows the operation of a solid-state imaging device 1 according to an embodiment of the invention.

FIG. 5 shows the detailed configuration of a solid-state imaging device 1 according to an embodiment of the invention.

FIGS. 6A and 6B are sectional views showing main parts in some processes in a method for producing a solid-state imaging device 1 according to an embodiment of the invention.

FIGS. 7A and 7B are sectional views showing main parts in some processes in a method for producing a solid-state imaging device 1 according to an embodiment of the invention.

FIGS. 8A and 8B are sectional views showing main parts in some processes in a method for producing a solid-state imaging device 1 according to an embodiment of the invention.

FIGS. 9A and 9B are sectional views showing main parts in some processes in a method for producing a solid-state imaging device 1 according to an embodiment of the invention.

FIG. 10 is a sectional view showing a main part in a process in a method for producing a solid-state imaging device 1 according to an embodiment of the invention.

### DESCRIPTION OF THE PREFERRED EMBODIMENTS

Embodiments of the invention are explained hereinafter with reference to the drawings.

The explanations will be given in following order.

1. Embodiments

2. Others

### 1. Embodiments

### Configuration of Device

### (1) Main Configuration of Camera

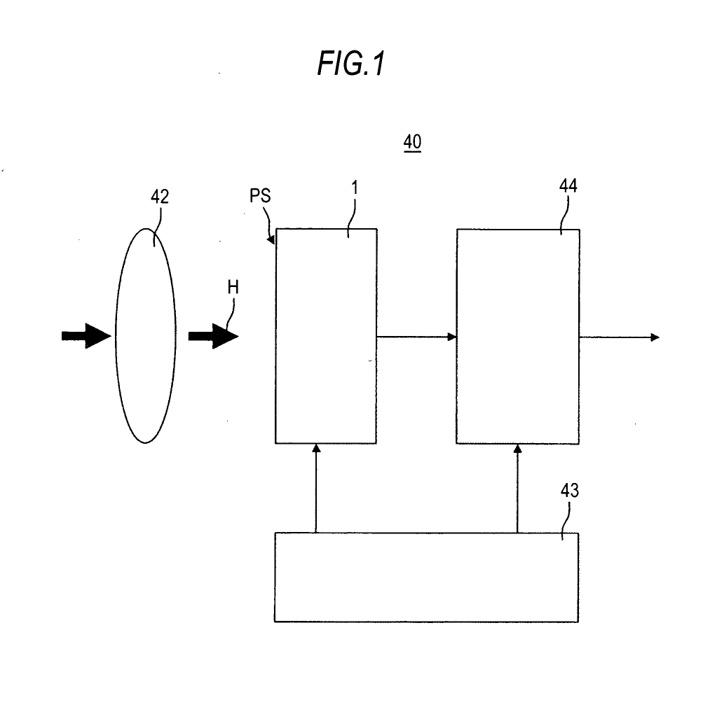

FIG. 1 is a block diagram showing the configuration of a camera 40 according to an embodiment of the invention.

As shown in FIG. 1, the camera 40 has a solid-state imaging device 1, an optical system 42, a drive circuit 43, and a signal processing circuit 44. Each component will be explained hereinafter.

The solid-state imaging device 1 receives, by an imaging surface PS thereof, light H (image of an object) entering through the optical system 42, and photoelectrically converts the light to generate signal charges. Here, the solid-state imaging device 1 is driven based on a drive signal that is output from the drive circuit 43. The signal charges are then read and output as raw data.

The optical system 42 is disposed to concentrate the incident light H of an image of an object to the imaging surface PS of the solid-state imaging device 1.

The drive circuit 43 outputs various drive signals to the solid-state imaging device 1 and the signal processing circuit 44, thereby driving the solid-state imaging device 1 and the signal processing circuit 44.

The signal processing circuit 44 is configured to process signals in the raw data output from the solid-state imaging device 1, thereby generating an digital image of the image of an object.

### (2) Main Configuration of Solid-State Imaging Device

The following explains the overall configuration of the solid-state imaging device 1.

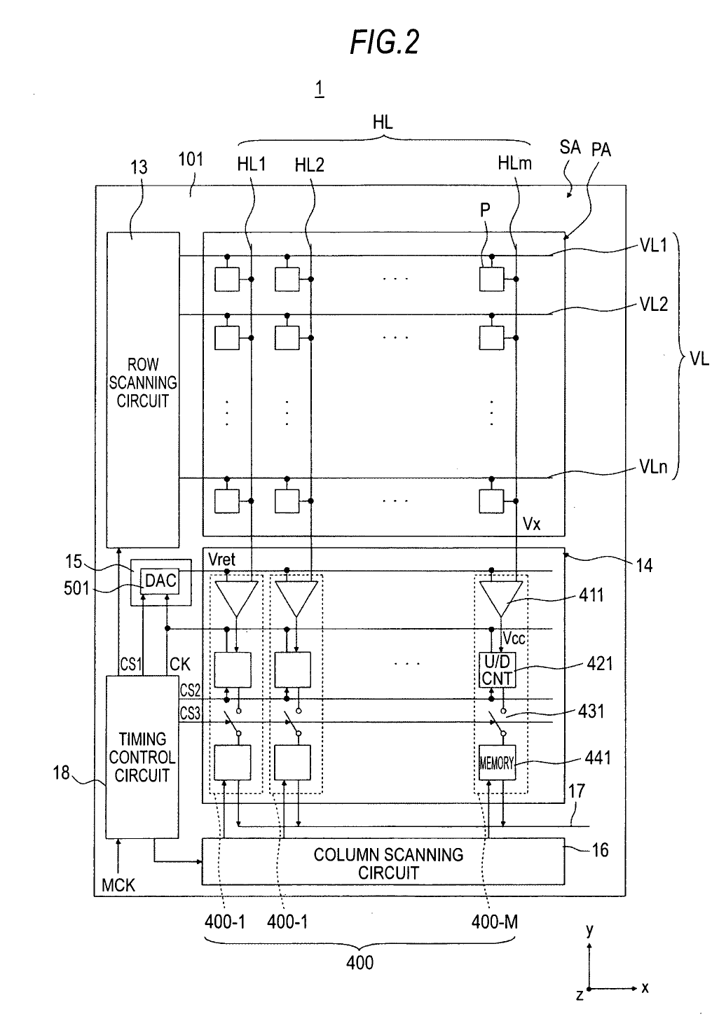

FIG. 2 schematically shows the configuration of a solid-state imaging device 1 according to an embodiment of the invention.

The solid-state imaging device 1 in this embodiment is a CMOS image sensor and includes a substrate 101 as shown in FIG. 2. The substrate 101 is a semiconductor substrate made of silicon, for example. As shown in FIG. 2, the surface of the substrate 101 includes an image sensing area PA and a peripheral area SA.

The following explains the image sensing area PA.

As shown in FIG. 2, the image sensing area PA has a rectangular shape, and includes a plurality of pixels P arranged both in the horizontal direction x and the vertical direction y. That is, the pixels P are arranged in the form of a matrix.

Specifically, as shown in FIG. 2, m pixels P are arranged in the horizontal direction x, and n pixels P are arranged in the vertical direction y. That is, a plurality of pixels P are arranged to give a pixel array of m columns and n rows. The detailed description of the pixels P will be given below.

The image sensing area PA includes row control lines VL. The row control lines VL are each electrically connected to a plurality of pixels P aligned in the horizontal direction x in the image sensing area PA. The row control lines VL are placed side by side in the vertical direction y for a plurality pixels P aligned in the vertical direction y. That is, the row control lines VL are provided in such a manner that a first row control line VL1 to an n-th row control line VLn are connected to the rows of pixels P (first to n-th rows) in the image sensing area PA, respectively.

The image sensing area PA also includes column signal lines HL. The column signal lines HL are each electrically connected to a plurality of pixels P aligned in the vertical direction y in the image sensing area PA. The column signal lines HL are placed side by side in the horizontal direction x for the plurality pixels P aligned in the horizontal direction x. That is, the column signal lines HL are provided in such a manner that a first column signal line HL1 to an m-th column signal line HLm are connected to the columns of pixels P (first to m-th columns) in the image sensing area PA, respectively.

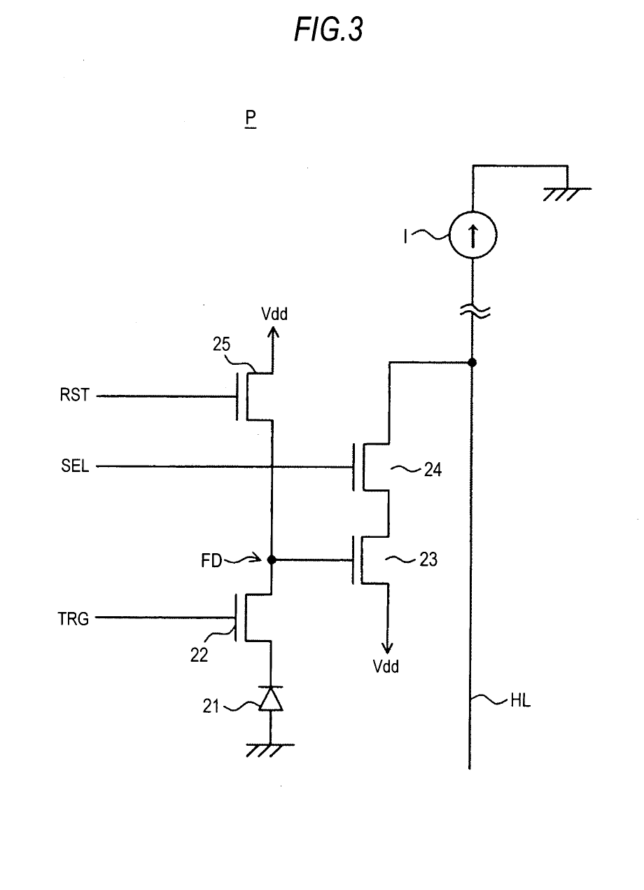

FIG. 3 is a circuit diagram showing the main part of a pixel P provided in an image sensing area PA according to an embodiment of the invention.

As shown in FIG. 3, each pixel P provided in the image sensing area PA includes a photodiode 21, a transfer transistor 22, an amplification transistor 23, a selection transistor 24, and a reset transistor 25. That is, the photodiode 21 and pixel transistors that read a signal charge from the photodiode 21 are provided therein.

In the pixel P, the photodiode 21 receives light of an image of an object, and photoelectrically converts the received light to generate and accumulate a signal charge. As shown in FIG. 3, the photodiode 21 is connected to a floating diffusion FD via the transfer transistor 22, so that the accumulated signal charge is transferred by the transfer transistor 22 as an output signal.

In the pixel P, the transfer transistor 22 is interposed between the photodiode 21 and the floating diffusion FD, as shown in FIG. 3. When a transfer pulse TRG is applied to the gate, the transfer transistor 22 transfers the signal charge accumulated in the photodiode 21 to the floating diffusion FD as an output signal.

In the pixel P, as shown in FIG. 3, the amplification transistor 23 has its gate connected to the floating diffusion FD, and is configured to amplify the output signal that is output via the floating diffusion FD. The amplification transistor 23 is connected to a column signal line HL via the selection transistor 24. When the selection transistor 24 is on, a source follower is formed between the amplification transistor 23 and a constant current source I that is connected to the column signal line HL.

In the pixel P, as shown in FIG. 3, the selection transistor 24 is configured so that a selection pulse SEL is supplied to the gate thereof. The selection transistor 24 selects pixels row by row to read signals therefrom. The selection transistor 24 turns on when a selection pulse SEL is supplied thereto. When the selection transistor 24 is on, as mentioned above, the amplification transistor 23 and the constant current source I form a source follower, so that a voltage correlated with the voltage of the floating diffusion FD is output to the column signal line HL.

In the pixel P, as shown in FIG. 3, the reset transistor 25 is configured so that a reset pulse RST is supplied to the gate thereof. The reset transistor 25 is also interposed between the power supply Vdd and the floating diffusion FD. When a reset pulse RST is supplied to the gate, the reset transistor 25 resets the electric potential of the floating diffusion FD to the electric potential of the power supply Vdd.

When various pulse signals are supplied from peripheral circuits in the below-mentioned peripheral area SA via the row control lines VL to the pixels P, the pixels P are sequentially selected and driven horizontal line by horizontal line (pixel row by pixel row).

The following explains the peripheral area SA.

As shown in FIG. 2, the peripheral area SA surrounds the periphery of the image sensing area PA. In the peripheral area SA, peripheral circuits SK are provided. In this embodiment, a row scanning circuit 13, a column circuit 14, a reference voltage supply 15, a column scanning circuit 16, and a timing control circuit 18 are provided as the peripheral circuits SK.

The row scanning circuit 13 includes a shift register (not illustrated), and is configured to select and drive pixels P row by row. As shown in FIG. 2, the plurality of row control lines VL are each electrically connected at one end thereof to the row scanning circuit 13. Via each row control line VL, the row scanning circuit 13 scans the pixels P in the image sensing area PA row by row.

Specifically, the row scanning circuit 13 outputs a reset pulse signal, a transfer pulse signal, and like various pulse signals via the row control lines VL to the pixels P row by row, thereby driving the pixels P.

The plurality of column signal lines HL are each electrically connected at one end thereof to the column circuit 14. The column circuit 14 is configured to process signals read out from the pixels P column by column.

As shown in FIG. 2, the column circuit 14 has an ADC (analog-to-digital conversion circuit) 400, and performs A/D conversion that converts analog signals output from pixels P into digital signals.

In the column circuit 14, a plurality of ADCs 400 are placed side by side in the horizontal direction x for the plurality pixel P columns placed side by side in the horizontal direction x in the image sensing area PA. That is, the ADCs 400 are provided in such a manner that a “first ADC 400-1” to an “m-th ADC 400-m” are provided for the columns of pixels P (first to m-th columns) in the image sensing area PA, respectively. In this manner, the plurality of ADCs 400 are mounted in parallel with the columns of pixels P. The plurality of ADCs 400 (400-1 to 400-m) are electrically connected to the plurality of column signal lines HL (HL1 to HLm) that are each provided for each column of pixels P, and performs A/D conversion of signals output from the pixels P column by column.

As shown in FIG. 2, the ADCs 400 each has a comparator 411, an up/down counter 421, a transfer switch 431, and a memory 441.

In each of the ADCs 400 forming the column circuit 14, the comparator 411 is electrically connected to a column signal line HL as shown in FIG. 2, and receives an input of signal voltages Vx output with respect to the corresponding column of pixels P. Further, the comparator 411 is electrically connected to the reference voltage supply 15 as shown in FIG. 2, and receives an input of a reference voltage Vref of a ramp waveform. The comparator 411 makes a comparison between an input signal voltage Vx and the reference voltage Vref. For example, when the reference voltage Vref is larger than the signal voltage Vx, the level of output Vco is high (H), while when the reference voltage Vref is the same as or lower than the signal voltage Vx, the level of output Vco is low (L).

In each of the ADCs 400 forming the column circuit 14, the up/down counter 421 is electrically connected to the comparator 411 as shown in FIG. 2, and receives the output Vco from the comparator 411. The up/down counter 421 is electrically connected to the timing control circuit 18 as shown in FIG. 2, and receives a control signal CS2 and a clock signal CK from the timing control circuit 18.

When the up/down counter 421 receives the control signal CS2, the clock signal CK is given simultaneously with a DAC 501. In synchronization with the clock signal CK, the up/down counter 421 alternately performs counting down (DOWN) and counting up (UP). The up/down counter 421 thereby measures the period of the comparison by the comparator 411.

The comparator 411 and the up/down counter 421 forming an ADC 400 thus convert an analog signal output via a column signal line HL from a pixel P in the image sensing area PA into an N-bit digital signal.

In each of the ADCs 400 forming the column circuit 14, the transfer switch 431 is configured to switch the connection to the up/down counter 421 as shown in FIG. 2. Further, the transfer switch 431 is electrically connected to the timing control circuit 18 as shown in FIG. 2, and configured to receive a control signal CS3 from the timing control circuit 18. The transfer switch 431 turns on based on the control signal CS3 and is thereby connected to the up/down counter 421, whereby the count value by the up/down counter 421 is output to the memory 441.

Specifically, the transfer switch 431 turns on at the time when the up/down counter 421 completes counting about a pixel P in a certain row, and transfers the obtained count value to the memory 441.

In each of the ADCs 400 forming the column circuit 14, the memory 441 is electrically connected to the transfer switch 431 as shown in FIG. 2, and configured to store digital signals that are input via the transfer switch 431.

The reference voltage supply 15 is electrically connected to the comparators 411 as shown in FIG. 2, and configured to output the reference voltage Vref of a ramp (RAMP) waveform to the comparators 411. The reference voltage supply 15 is electrically connected to the timing control circuit 18 as shown in FIG. 2, and configured to receive a control signal CS1 and a clock signal CK from the timing control circuit 18.

Specifically, the reference voltage supply 15 includes a DAC 501. Under control of the control signal CS1 output from the timing control circuit 18, the DAC 501 generates the reference voltage Vref of a ramp waveform based on the clock signal CK.

The column scanning circuit 16 includes a shift register (not illustrated), and is configured to select the column of pixels P and output a digital signal from the column circuit 14 to a horizontal output line 17. The column scanning circuit 16 is electrically connected to the plurality of ADCs 400 forming the column circuit 14 as shown in FIG. 2, so that signals read from the pixels P via the column circuit are sequentially output in the horizontal direction x to the horizontal output line 17.

The horizontal output line 17 is electrically connected to the column circuit 14 as shown in FIG. 2, and outputs a digital signal of the column selected by the column scanning circuit 16.

The timing control circuit 18 is configured to, based on a master clock CK0, generate a drive signal for each component and then output the signal to each component.

### (3) Operation of Solid-State Imaging Device

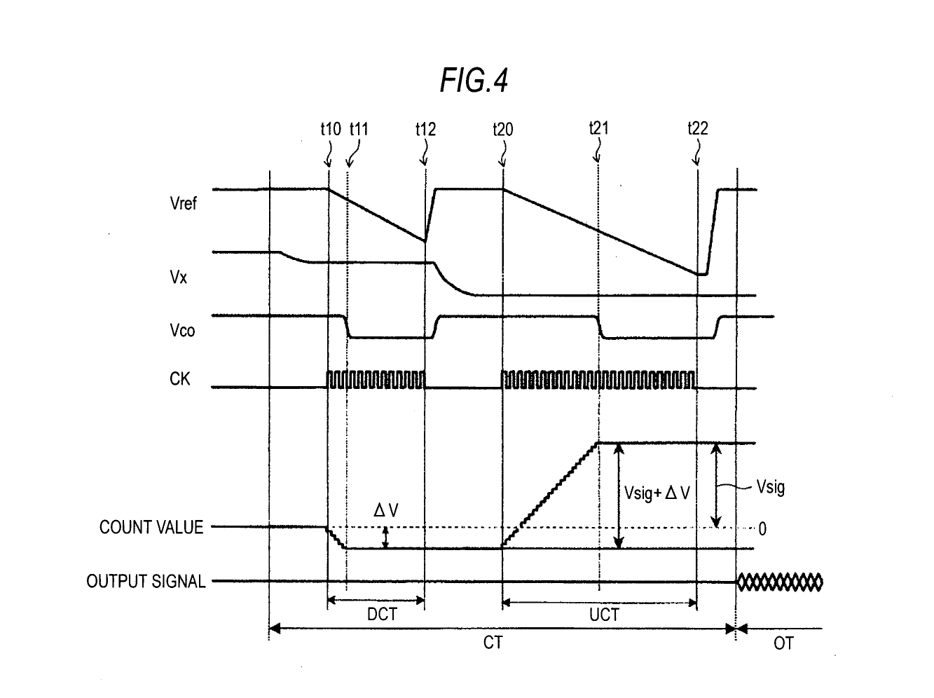

FIG. 4 shows the operation of a solid-state imaging device 1 according to an embodiment of the invention. FIG. 4 shows a timing chart at the time of driving the ADCs 400 forming the column circuit 14. The detail is given in the above-mentioned JP-A-2005-278135 and JP-A-2005-323331.

As shown in FIG. 4, in the A/D conversion period CT, a first readout is performed first. In the first readout, as shown in FIG. 4, with respect to an analog signal output from a pixel P via a column signal line HL, a count value corresponding to the magnitude of a reset component ΔV containing noise is read out.

Specifically, as shown in FIG. 4, in the first readout, at first (at the time of t10), a reference voltage Vref of a ramp waveform and a clock signal CK are given simultaneously. Specifically, the clock signal CK is input in synchronization with an input of the reference voltage Vref of a ramp waveform.

The reference voltage Vref of a ramp waveform is applied to the comparator 411 of an ADC 400 via the DAC 501, as shown in FIG. 2. The comparator 411 thereby compares the signal voltage Vx of the column signal line HL with the reference voltage Vref.

The clock signal CK is applied from the timing control circuit 18 to the up/down counter 421, as shown in FIG. 2. The up/down counter 421 thereby measures the comparison time of the comparator 411. Here, the comparison time is measured by a down-count operation. Specifically, the counting operation is performed so as to count backwards from the initial value “0”. For example, the down-count operation is performed for a down-count period DCT of 7 bits (128 clocks).

Next, as shown in FIG. 4, when the reference voltage Vref and the signal voltage Vx become equal (at the time of t11), the output Vco of the comparator 411 is reversed. Specifically, the output Vco is reversed from high level to low level.

The output Vco is applied to the up/down counter 421, as shown in FIG. 2.

At this time, in the up/down counter 421, as shown in FIG. 4, in response to the reversal of polarity of the output Vco, the down-count operation is stopped, and the count value corresponding to the comparison period of the comparator 411 is retained. Here, as shown in FIG. 4, the count value corresponding to the magnitude of the reset component ΔV is retained there.

Subsequently, as shown in FIG. 4, after the down-count period DCT has elapsed (at the time of t12), the supply of the reference voltage Vref of a ramp waveform and the clock signal CK is stopped.

As mentioned above, in the A/D conversion period, after the completion of the first readout, the second readout is performed as shown in FIG. 4.

In the second readout, as shown in FIG. 4, the signal component Vsig corresponding to the amount of light incident on the pixel P is read out as in the first readout.

Specifically, as shown in FIG. 4, in the second readout, at first (at the time of t20), a reference voltage Vref of a ramp waveform and a clock signal CK are given simultaneously.

Here, in response to the application of the reference voltage Vref of a ramp waveform, the comparator 411 compares the signal voltage Vx of the column signal line HL with the reference voltage Vref. The reference voltage Vref in the second readout is applied so that the slope of the ramp waveform is the same as in the first readout.

Further, in response to the application of the clock signal CK, the up/down counter 421 measures the comparison time of the comparator 411. Unlike the first readout, the measurement is performed by an up-count operation as shown in FIG. 4. Specifically, the counting operation is performed so as to count upwards from the count value corresponding to the reset component ΔV. For example, the up-count operation is performed for an up-count period UCT of 10 bits (1024 clocks).

Accordingly, the up/down counter 421 performs a subtraction of the “first comparison period” from the “second comparison period”.

Next, as shown in FIG. 4, when the reference voltage Vref and the signal voltage Vx become equal (at the time of t21), the polarity of the output Vco of the comparator 411 is reversed.

At this time, as shown in FIG. 4, in response to the reversal of polarity of the output Vco, the up/down counter 421 stops counting, and retains the count value obtained by the above subtraction.

The count value obtained by subtracting the “first comparison period” from the “second comparison period” has the following relation. Specifically, by the above subtraction, not only the reset component ΔV but also the offset component of the ADC 400 is removed.

(Second comparison period)−(first comparison period)=(Vsig+ΔV+offset component of ADC 400)−(ΔV+offset component of ADC 400)=Vsig

Subsequently, as shown in FIG. 4, after the up-count period UCT has elapsed (at the time of t22), the supply of the reference voltage Vref of a ramp waveform and the clock signal CK is stopped.

Thus, in this embodiment, CDS (Correlated Double Sampling) processing as above is performed to make conversion into a digital signal.

After the A/D conversion, the thus-generated n-bit digital signal is retained in the up/down counter 421.

Subsequently, as shown in FIG. 4, in the signal output period OT, the digital signal is transferred to the memory 441, and output from the horizontal output line 17 to the exterior. Specifically, the transfer switch 431 turns on at the time when the up/down counter 421 completes counting about a pixel P in a certain row, and the digital signal is transferred to the memory 441. The above operation is repeated for all rows of pixels P, thereby producing a two-dimensional image.

### (4) Detailed Configuration of Solid-State Imaging Device

The following provides a detailed explanation of the solid-state imaging device 1 according to this embodiment.

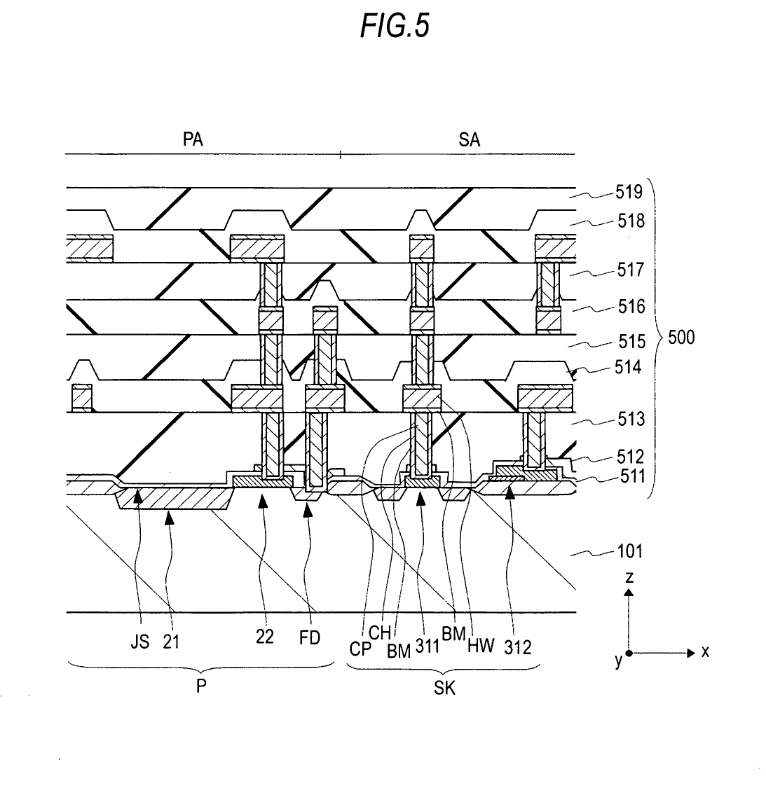

FIG. 5 shows the detailed configuration of a solid-state imaging device 1 according to an embodiment of the invention. FIG. 5 shows a section of the main part of the image sensing area PA and the peripheral area SA in the solid-state imaging device 1.

The solid-state imaging device 1 includes pixels P in the image sensing area PA as shown in FIG. 5. FIG. 5 shows a part of an image sensing element forming a pixel P, and a photodiode 21 and a transfer transistor 22 are mounted on the substrate 101.

In addition, although not illustrated in FIG. 5, the components shown in FIG. 2 and FIG. 3 are also provided in the image sensing area PA.

The peripheral area SA includes peripheral circuits SK. FIG. 5 shows some peripheral circuit elements forming a peripheral circuit SK, and a transistor 311 and a capacitor 312 are provided.

For example, the transistor 311 is a semiconductor element that forms the above-mentioned comparator 411 (see FIG. 2). The transistor 311 is an n-channel MOSFET, for example.

In addition, although not illustrated in FIG. 5, the components shown in FIG. 2 and FIG. 3 are also provided in the peripheral area SA.

The substrate 101 has formed thereon an interconnect layer 500.

The interconnect layer 500 includes insulation films 511 to 519, contact plugs CP, and metal interconnects HW, as shown in FIG. 5.

As shown in FIG. 5, in the interconnect layer 500, the insulation films 511 to 519 are formed to cover the image sensing element forming a pixel P and the peripheral circuit elements forming a peripheral circuit SK.

As shown in FIG. 5, of the plurality of insulation films 511 to 519, the first insulation film 511 covers the top surface of the substrate 101, where the image sensing element forming a pixel P and the peripheral circuit elements forming a peripheral circuit SK are formed. The first insulation film 511 is an SiO₂ film, for example.

Of the plurality of insulation films 511 to 519, the second insulation film 512 is laminated on the top surface of the first insulation film 511 as shown in FIG. 5. The second insulation film 512 is an LP-SiN film and has a thickness of a few tens of nanometers, for example.

As described below in detail, in this embodiment, the second insulation film 512 is formed to serve as an etching stopper layer during anisotropic etching to form a contact hole CH in the third insulation film 513. As mentioned above, in anisotropic etching, the etch selectivity is low between insulation films (SiO₂-based), element electrodes (polysilicon, tungsten), and the substrate 101 (silicon substrate). Therefore, the second insulation film 512 is formed as an etching stopper layer.

Although not illustrated in FIG. 5, the second insulation film 512 is formed to cover a portion where a contact hole CH is to be formed in the third insulation film 513 by the above-mentioned etching. Prior to the etching, the second insulation film 512 is patterned so that portions other than the portion where the contact hole is to be formed in the third insulation film 513 are exposed. Further, as shown in FIG. 5, the second insulation film 512 is also etched to form a contact hole CH therein, and a contact plug CP is provided to fill the contact hole CH.

Thus, the contact hole CH in the second insulation film 512 is formed by etching the second insulation film 512 after etching the third insulation film 513. That is, the third insulation film 513, an upper layer, is etched so as to remove a portion thereof where a contact hole is to be formed. Subsequently, the second insulation film 512 is etched so as to remove a portion thereof where a contact hole is to be formed. Contact holes CH are thus formed in the second insulation film 512.

Of the plurality of insulation films 511 to 519, the third insulation film 513 is laminated on the top surface of the second insulation film 512 as shown in FIG. 5. The third insulation film 513 is formed to planarize the surface of the substrate 101 provided with the second insulation film 512. The third insulation film 513 is provided with a plurality of contact plugs CP that pass through the third insulation film 513 and also through the first and second insulation films 511 and 512. Further, metal interconnects HW are provided on the top surface of the third insulation film 513. The third insulation film 513 is an SiO₂ film such as a LP-TEOS film, and has a thickness of a few hundreds of nanometers, for example.

Of the plurality of insulation films 511 to 519, the fourth insulation film 514 is laminated on the top surface of the third insulation film 513 as shown in FIG. 5. The fourth insulation film 514 is formed to cover the metal interconnects HW provided on the top surface of the third insulation film 513. The fourth insulation film 514 is an SiO₂ film such as a LP-TEOS film, and has a thickness of a few hundreds of nanometers, for example.

Of the plurality of insulation films 511 to 519, the fifth insulation film 515 is laminated on the top surface of the fourth insulation film 514 as shown in FIG. 5. The fifth insulation film 515 is formed to planarize the surface of the substrate 101 provided with the fourth insulation film 514. The fifth insulation film 515 is provided with a plurality of contact plugs CP that pass through the fifth insulation film 515 and also through the fourth insulation film 514. Further, metal interconnects HW are provided on the top surface of the fifth insulation film 515. The fifth insulation film 515 is an SiO₂ film such as an LP-TEOS film, and has a thickness of a few hundreds of nanometers, for example.

Of the plurality of insulation films 511 to 519, the sixth insulation film 516 is laminated on the top surface of the fifth insulation film 515 as shown in FIG. 5. The sixth insulation film 516 is formed to cover the metal interconnects HW provided on the top surface of the fifth insulation film 515. The sixth insulation film 516 is an SiO₂ film such as an LP-TEOS film, and has a thickness of a few hundreds of nanometers, for example.

Of the plurality of insulation films 511 to 519, the seventh insulation film 517 is laminated on the top surface of the sixth insulation film 516 as shown in FIG. 5. The seventh insulation film 517 is formed to planarize the surface of the substrate 101 provided with the sixth insulation film 516. The seventh insulation film 517 is provided with a plurality of contact plugs CP that pass through the seventh insulation film 517 and also through the sixth insulation film 516. Further, metal interconnects HW are provided on the top surface of the seventh insulation film 517. The seventh insulation film 517 is an SiO₂ film such as an LP-TEOS film, and has a thickness of a few hundreds of nanometers, for example.

Of the plurality of insulation films 511 to 519, the eighth insulation film 518 is laminated on the top surface of the seventh insulation film 517 as shown in FIG. 5. The eighth insulation film 518 is formed to cover the metal interconnects HW provided on the top surface of the seventh insulation film 517. The eighth insulation film 518 is an SiO₂ film such as an LP-TEOS film, and has a thickness of a few hundreds of nanometers, for example.

Of the plurality of insulation films 511 to 519, the ninth insulation film 519 is laminated on the top surface of the eighth insulation film 518 as shown in FIG. 5. The ninth insulation film 519 is formed to planarize the surface of the substrate 101 provided with the eighth insulation film 518. The ninth insulation film 519 is an SiO₂ film such as an LP-TEOS film, and has a thickness of a few hundreds of nanometers, for example.

As shown in FIG. 5, in the interconnect layer 500, the contact plugs CP are formed above the image sensing element forming a pixel P and the peripheral circuit elements forming a peripheral circuit SK, making electrical connection to the elements. The contact plugs CP are formed to fill the contact holes CH that are formed through any of the insulation film 511 to 519 forming the interconnect layer 500.

Specifically, as shown in FIG. 5, the contact plugs CP are formed through the first to third insulation films 511 to 513, and each has a portion connected to the image sensing element forming a pixel P or a peripheral circuit element forming a peripheral circuit SK.

Further, as shown in FIG. 5, the contact plugs CP are also formed through the fourth and fifth insulation films 514 and 515, and each has a portion electrically connected via a metal interconnect HW to the lower contact plug CP that passes through the first to third insulation film 511 to 513.

Further, as shown in FIG. 5, the contact plugs CP are also formed through the sixth and seventh insulation films 516 and 517, and each has a portion electrically connected via a metal interconnect HW to the lower contact plug CP that passes through the fourth and fifth insulation films 514 and 515.

Each contact plug CP has a barrier metal BM on the bottom and the side thereof as shown in FIG. 5.

In the interconnect layer 500, as shown in FIG. 5, the metal interconnects HW are each interposed between any of the insulation films 511 to 519, and electrically connected to the contact plugs CP.

Specifically, as shown in FIG. 5, the metal interconnects HW are provided on the third insulation film 513 and covered with the fourth insulation film 514. The metal interconnects HW on the third insulation film 513 are each interposed between a contact plug CP that passes through the first to third insulation films 511 to 513 and a contact plug CP that passes through the fourth and fifth insulation films 514 and 515, and have a portion that electrically connects to the two.

Further, as shown in FIG. 5, the metal interconnects HW are also provided on the fifth insulation film 515 and covered with the sixth insulation film 516. The metal interconnects HW on the fifth insulation film 515 are each interposed between a contact plug CP that passes through the fourth and fifth insulation films 514 and 515 and a contact plug CP that passes through the sixth and seventh insulation films 516 and 517, and have a portion that electrically connects the two.

Further, as shown in FIG. 5, the metal interconnects HW are also provided on the seventh insulation film 517 and covered with the eighth insulation film 518. The metal interconnects HW on the seventh insulation film 517 each have a portion that is electrically connected to a contact plug CP that passes through the sixth and seventh insulation films 516 and 517.

As shown in FIG. 5, each metal interconnect HW has a barrier metal BM on the top and lower surfaces thereof.

In this embodiment, as shown in FIG. 5, the metal interconnects HW are each provided at a portion where a contact hole CH is formed above a peripheral circuit element (e.g., transistor 311) forming a peripheral circuit SK. Further, no metal interconnect HW is provided at portions other than the portion where the contact hole CH is formed above the peripheral circuit element (e.g., transistor 311) forming a peripheral circuit SK.

### [Production Method]

The following explains important parts of a method for producing the above-described solid-state imaging device 1.

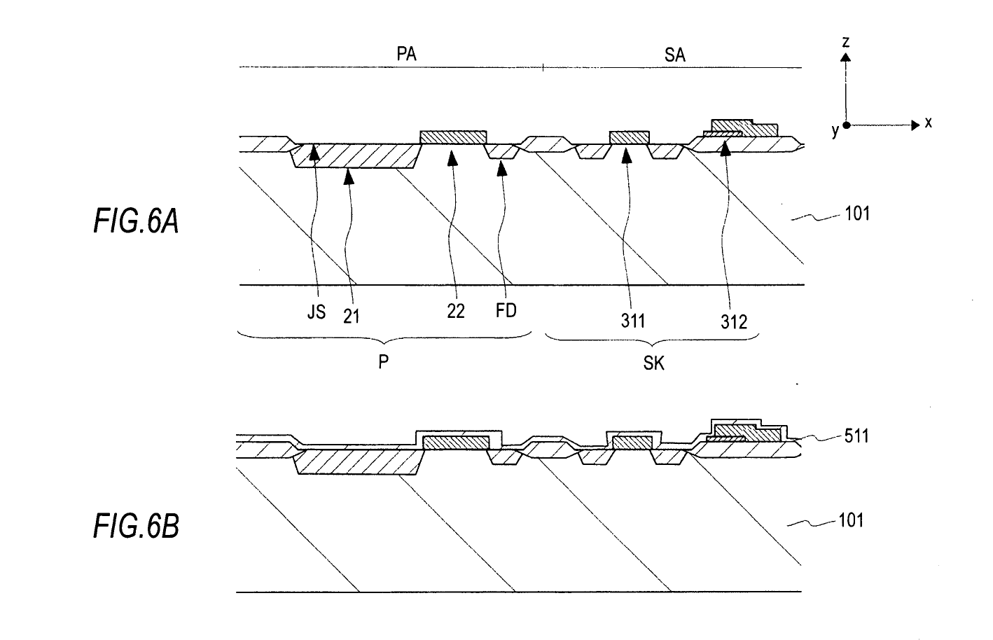

FIGS. 6A to 10 are sectional views showing main parts in the processes in a method for producing a solid-state imaging device 1 according to an embodiment of the invention. As FIG. 5, FIGS. 6A to 10 each show a section of a main part of the image sensing area PA and the peripheral area SA in the solid-state imaging device 1.

(1) Formation of Image sensing elements and Peripheral Circuit Elements

First, as shown in FIG. 6A, an image sensing element forming a pixel P and peripheral circuit elements forming a peripheral circuit SK are formed on the top surface of the substrate 101.

In the image sensing area PA, as a part of the image sensing element forming a pixel P, the photodiode 21 and the transfer transistor 22 are provided on the substrate 101 as shown in FIG. 6A. In addition, although not illustrated therein, the components shown in FIG. 2 and FIG. 3 are also provided in the image sensing area PA.

In the peripheral area SA, as some of the peripheral circuit elements forming a peripheral circuit SK, the transistor 311 and the capacitor 312 are provided. For example, the transistor 311 is provided as a semiconductor element that forms the above-mentioned comparator 411 (see FIG. 2). In addition, although not illustrated therein, the components shown in FIG. 2 and FIG. 3 are also provided in the peripheral area SA.

### (2) Formation of First Insulation Film 511

Next, as shown in FIG. 6B, a first insulation film 511 is formed to cover the top surface of the substrate 101, where the image sensing element forming a pixel P and the peripheral circuit elements forming a peripheral circuit SK are provided.

The first insulation film 511 is formed as a SiO₂ film, for example.

### (3) Formation of Second Insulation Film 512

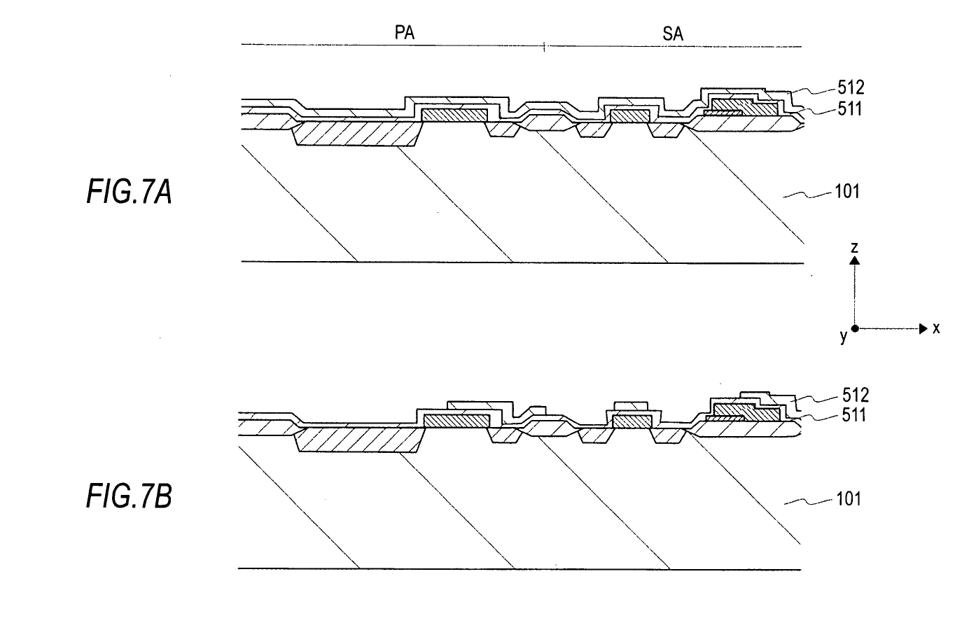

Next, as shown in FIG. 7A, a second insulation film 512 is laminated to the first insulation film 511 to cover the entire top surface of the first insulation film 511.

Here, the second insulation film 512 is formed to serve as an etching stopper layer during etching of the below-mentioned third insulation film 513. That is, the second insulation film 512 is formed to provide a high etch selectivity with respect to the third insulation film 513.

Specifically, the second insulation film 512 is formed under the following conditions to have the following characteristics, so that the second insulation film 512 serves as an etching stopper layer.

Temperature: 700° C. to 800° C.

Pressure: 20 Pa to 40 Pa

Film formation rate: 1 nm/min to 5 nm/min

Gas: SiH₂Cl₂/NH₃=160/1600 sccm

Film thickness: 10 nm to 50 nm

Density: in wet etching using DHF, the etch rate with respect to P-SiN=1/5 to 1/20

The thus-formed second insulation film 512 is an LP-SiN film having a thickness of a few tens of nanometers, for example. That is, a film of silicon nitride is formed by low-pressure CVD to give the second insulation film 512.

### (4) Patterning of Second Insulation Film 512

Next, as shown in FIG. 7B, the second insulation film 512 is patterned to cover a part of the upper surface of the first insulation film 511 and expose other parts.

Here, the second insulation film 512 is processed to cover a portion where a contact hole (not illustrated) is to be formed above a peripheral circuit element forming a peripheral circuit SK, with portions other than the portion where the contact hole (not illustrated) is to be formed being exposed (see FIG. 5).

Specifically, the second insulation film 512 is processed to cover a portion where a contact hole (not illustrated) is to be formed above the transistor 311 that is the semiconductor element forming the comparator 411 (see FIG. 2), with other portions being exposed.

At the same time, the second insulation film 512 is processed not to cover the top surface of the light-receiving surface JS of the photodiode 21.

Specifically, a photomask is formed by photolithography, and then the second insulation film 512 is etched using the photomask; the second insulation film 512 is thus processed as above.

### (5) Formation of Third Insulation Film 513

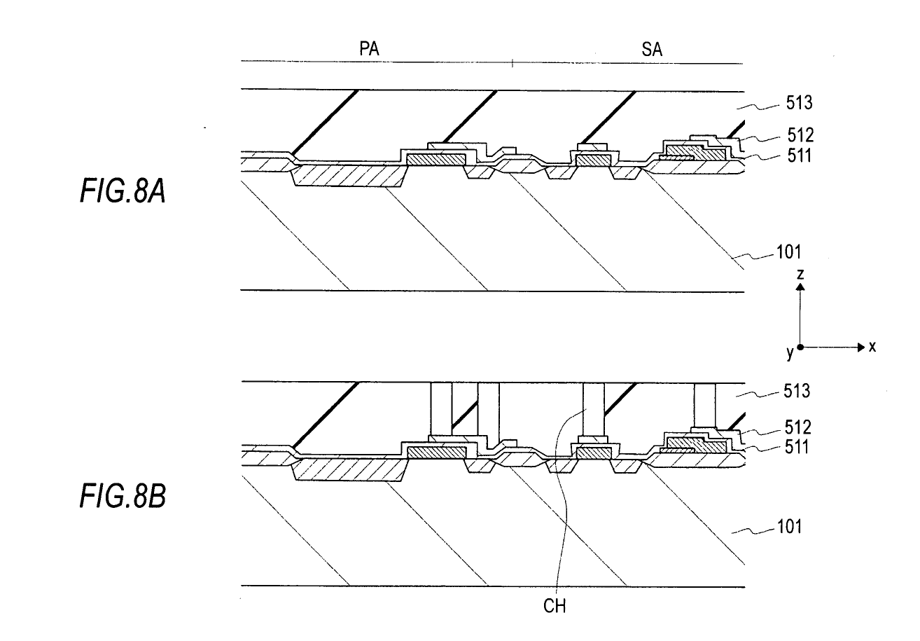

Next, as shown in FIG. 8A, the third insulation film 513 is formed to cover the top surface of the thus-patterned second insulation film 512.

Here, as the third insulation film 513, an SiO₂ film such as an LP-TEOS film is formed to a thickness of a few hundreds of nanometers, for example. The surface thereof is then planarized to give the third insulation film 513. The surface planarization is performed by CMP (Chemical Mechanical Polishing), for example.

### (6) Formation of Contact Holes CH in Third Insulation Film 513

Next, as shown in FIG. 8B, contact holes CH are formed in the third insulation film 513.

Here, the contact holes CH are formed in the third insulation film 513 so that the contact holes CH pass through portions corresponding to the portions where contact plugs CP (see FIG. 5) are to be formed in the third insulation film 513.

Specifically, a photoresist mask (not illustrated) is formed by photolithography, and then the third insulation film 513 is subjected to anisotropic dry etching using the photoresist mask, thereby forming the contact holes CH. The contact holes CH are thus formed in such a manner that the sides of the contact holes CH extend along the direction z that is perpendicular to the plane of the substrate 101.

In this embodiment, the above dry etching is performed so that the second insulation film 512 located under the third insulation film 513 serves as an etching stopper layer. Specifically, the dry etching is performed to secure sufficient etch selectivity between the SiN film, i.e., the second insulation film 512, and the SiO₂ film, i.e., the third insulation film 513.

The dry etching is performed under the following conditions, for example.

Pressure: 30 mTorr

Gas: Ar/C₄F₆/CO/O₂=900/21/40/21 sccm

Power: 2000/2400 W

### (7) Formation of Contact Holes CH in First and Second Insulation Films 511 and 512

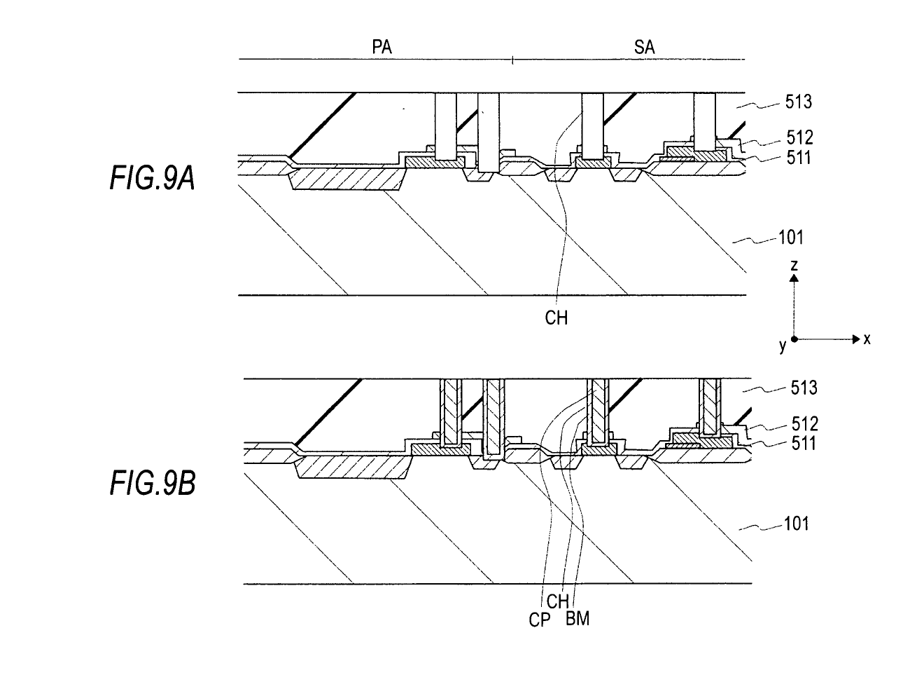

Next, as shown in FIG. 9A, contact holes CH are formed in the first insulation film 511 and the second insulation film 512.

Here, the contact holes CH are formed in the first and second insulation films 511 and 512 in such a manner that the contact holes CH formed in the third insulation film 513 further extend downwards.

Specifically, in the same manner as above, the first and second insulation films 511 and 512 are subjected to anisotropic dry etching to form the contact holes CH. As a result, the surface of an electrode or a diffusion layer of an element in the lower layer is exposed, whereby the contact holes CH are formed.

In this embodiment, the dry etching is performed to secure sufficient etch selectivity between electrodes (e.g., polysilicon) or diffusion layers (Si) of the elements in the lower layer and the first and second insulation films 511 and 512 (SiO₂ film and SiN film).

The dry etching is performed under the following conditions, for example.

[Second insulation film 512 (SiN film)]
Pressure: 20 mTorr
Gas: Ar/O₂/CF₄/CH₂F₂=300/30/30/30 sccm
Power: 500/300 W

[First insulation film 511 (SiO₂ film)]
Pressure: 30 mTorr
Gas: Ar/C₄F₆/CO/O₂=900/21/40/21 sccm
Power r: 1500/1700 W
Hydrogenation is then performed.

The hydrogenation is performed under the following conditions, for example.

Temperature: 350° C. to 400° C.

Time: 60 min to 1200 min

Gas: H₂/N₂=4/96 to 100/0 or D₂/N₂, or T₂/N₂

TTL flow rate: 10000 sccm

### (8) Formation of Contact Plugs CP

Next, as shown in FIG. 9B, contact plugs CP are formed in the contact holes CH.

Here, after applying a barrier metal BM to cover the bottom and the side of each contact hole CH, the contact hole CH is filled with a metal material, thereby giving a contact plug CP. The contact plugs CP are formed using tungsten, for example.

As a result, the contact plugs CP are formed making electrical connection to the image sensing element forming a pixel P or the peripheral circuit elements forming a peripheral circuit SK.

(9) Formation of Metal Interconnects HW and so forth

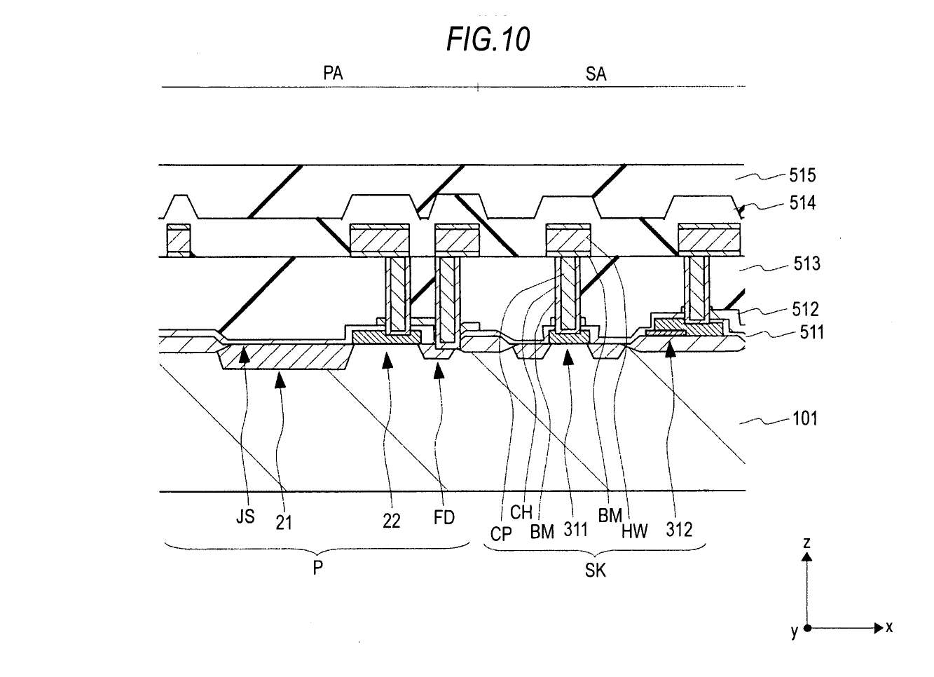

Next, as shown in FIG. 10, metal interconnects HW, a fourth insulation film 514, and a fifth insulation film 515 are formed.

The metal interconnects HW are formed on the third insulation film 513. The metal interconnects HW are formed using aluminum, for example.

Then, the fourth insulation film 514 is formed to cover the metal interconnects HW provided on the top surface of the third insulation film 513.

Then, as shown in FIG. 10, the fifth insulation film 515 is formed to planarize the surface of the substrate 101 having the fourth insulation film 514.

Subsequently, other components are formed as shown in FIG. 5, and hydrogenation is then performed.

The hydrogenation is performed under the following conditions, for example.

Temperature: 350° C. to 400° C.

Time: 60 min to 1200 min

Gas: H₂/N₂=4/96 to 100/0 or D₂/N₂, or T₂/N₂

TTL flow rate: 10000 sccm

A solid-state imaging device 1 is thus completed.

### (Sum-Up)

In summary, as described above, in this embodiment, the second insulation film 512 is formed to serve as an etching stopper layer during etching to form contact holes CH in the third insulation film 513. Here, prior to the etching, the second insulation film 512 is patterned to cover a portion where a contact hole is to be formed above a peripheral circuit element forming a peripheral circuit SK, with other portions being exposed. In particular, the second insulation film 512 is patterned to cover a portion where a contact hole is to be formed above a peripheral circuit element such as the transistor 311 forming the comparator 411 that compares an analog signal output from a pixel P with a reference signal, with other portions being exposed. Hydrogenation is subsequently performed.

In this embodiment, at the time of hydrogenation, the second insulation film (etching stopper layer) that interferes with the permeation of hydrogen is not formed at portions other than a portion where a contact hole is to be formed above a peripheral circuit element such as the transistor 311. That is, of the plurality of insulation films 511 to 519 forming the interconnect layer 500, the second insulation film 512, which has lower hydrogen permeability than other insulation films 511 and 513 to 519, is formed only at the above portion. As a result, a peripheral circuit element such as the transistor 311 suitably receives the effect of hydrogenation.

Accordingly, in this embodiment, the captured image quality can be prevented from being reduced due to peripheral circuits SK. Therefore, the captured image quality can be improved.

Further, in this embodiment, a metal interconnect HW is provided at a portion where a contact hole CH is formed above a peripheral circuit element such as the transistor 311, and no metal interconnect HW is provided at other portions. Hydrogenation is subsequently performed.

That is, at the time of hydrogenation, like the second insulation film 512, the metal interconnect HW that interferes with the permeation of hydrogen is formed only at a portion where a contact hole is to be formed above a peripheral circuit element such as the transistor 311. As a result, the peripheral circuit element such as the transistor 311 suitably receives the effect of hydrogenation.

### <2. Others>

The invention is not limited to the above embodiment, and various modifications can be made thereto.

The above embodiment describes the case where the second insulation film 512 is patterned to cover a portion where a contact hole is to be formed above the transistor 311 forming the comparator 411, with other portions being exposed. The above embodiment also describes the case where a metal interconnect HW is provided at a portion where a contact hole is formed above the transistor 311 forming the comparator 411, and is not provided at other portions.

However, the invention is not limited to the case of the transistor 311 forming the comparator 411.

For example, the second insulation film 512 may also be patterned to cover a portion where a contact hole is to be formed above a peripheral circuit element such as the transistor forming the DAC 501 that generates the reference signal (reference voltage Vref), with other portions being exposed. Likewise, the metal interconnect HW may also be provided at a portion where a contact hole is formed above the transistor forming the DAC 501, with no metal interconnect HW being provided at other portions.

As mentioned above, it has been found out that a DAC 501 can also cause random noise. Therefore, the same effects as in the above embodiment can be provided.

Further, although the above embodiment describes the case where hydrogenation is performed twice, the invention is not limited thereto. For example, the invention is also applicable to the case where hydrogenation is performed once. Further, the invention is also applicable to the case where hydrogenation is performed three times.

Further, although the above embodiment describes the case where the invention is applied to the camera 40, the invention is not limited thereto. The invention is also applicable to a scanner, a copier, or a like electronic apparatus equipped with a solid-state imaging device.

The solid-state imaging device 1 in the above embodiment is an example of the solid-state imaging device of the invention. The camera 40 in the above embodiment is an example of the electronic apparatus of the invention. The substrate 101 in the above embodiment is an example of the semiconductor substrate of the invention. The transistor 311 in the above embodiment is an example of the peripheral circuit element of the invention. The comparator 411 in the above embodiment is an example of the comparator of the invention. The DAC 501 in the above embodiment is an example of the digital-to-analog converter circuit of the invention. The second insulation film 512 in the above embodiment is an example of the first insulation film of the invention. The third insulation film 513 in the above embodiment is an example of the second insulation film of the invention. The contact hole CH in the above embodiment is an example of the contact hole of the invention. The contact plug CP in the above embodiment is an example of the contact plug of the invention. The metal interconnect HW in the above embodiment is an example of the metal interconnect of the invention. The pixel P in the above embodiment is an example of the image sensing element of the invention. The image sensing area PA in the above embodiment is an example of the image sensing area of the invention. The peripheral area SA in the above embodiment is an example of the peripheral area of the invention.

It should be understood by those skilled in the art that various modifications, combinations, sub-combinations and alterations may occur depending on design requirements and other factors insofar as they are within the scope of the appended claims or the equivalents thereof.

What is claimed is:

1. A method for producing a solid-state imaging device, comprising:
an element-forming process of forming a peripheral circuit element on a semiconductor substrate having an image sensing area where an image sensing element that captures an image of an object is provided and a peripheral area located on the periphery of the image sensing area, the peripheral circuit element being in the peripheral area;
an insulation-film-forming process of forming a plurality of insulation films so as to cover at least the peripheral circuit element;
a contact-hole-forming process of forming a contact hole through the plurality of insulation films and above the peripheral circuit element, the contact hole receiving a contact plug that is electrically connected to the peripheral circuit element; and
a hydrogenation process of subjecting the semiconductor substrate having the plurality of insulation films to hydrogenation;
the insulation-film-forming process including
a first-insulation-film-forming step of forming as one of the insulation films a first insulation film, and
a second-insulation-film-forming step of forming as one of the insulation films a second insulation film to cover the first insulation film,
the contact-hole-forming process including
a first etching step of etching the second insulation film so as to remove a portion thereof where the contact hole is to be formed, and
a second etching step of, after the first etching step, etching the first insulation film so as to remove a portion thereof where the contact hole is to be formed,
the first-insulation-film-forming step including
forming the first insulation film to serve as an etching stopper layer during etching in the first etching step, and also
forming the first insulation film to cover a portion where the contact hole is to be formed above the peripheral circuit element, with portions other than the portion where the contact hole is to be formed above the peripheral circuit element being exposed.

2. A method for producing a solid-state imaging device according to claim 1, wherein:
the element-forming process forms as the peripheral circuit element a semiconductor element forming a comparator that compares an analog signal output from the image sensing element with a reference signal; and,
in the first-insulation-film forming step, the first insulation film is formed to cover a portion where the contact hole is to be formed above the semiconductor element forming a comparator, with portions other than the portion where the contact hole is to be formed above the peripheral circuit element being exposed.

3. A method for producing a solid-state imaging device according to claim 1 or 2, wherein:
the element-forming process forms as the peripheral circuit element a semiconductor element forming a digital-to-analog converter circuit that produces the reference signal; and,
in the first-insulation-film forming step, the first insulation film is formed to cover a portion where the contact hole is to be formed above the semiconductor element forming a digital-to-analog converter circuit, with portions other than the portion where the contact hole is to be formed above the peripheral circuit element being exposed.

4. A method for producing a solid-state imaging device according to claim 1, further comprising
a contact-plug-forming process of forming a contact plug in the contact hole, and
a metal-interconnect-forming process of forming a metal interconnect that is electrically connected to the contact plug, the metal interconnect being interposed between the plurality of insulation films, and wherein
the hydrogenation process includes
a first hydrogenation step of performing, prior to the contact-plug-forming process, first hydrogenation as the hydrogenation, and
a second hydrogenation step of further performing, after the metal-interconnect-forming process, second hydrogenation as the hydrogenation.

5. A method for producing a solid-state imaging device according to claim 4, wherein:
in the metal-interconnect-forming process, the metal interconnect is formed so that the metal interconnect is provided at a portion where the contact hole is formed above the peripheral circuit element and is not provided at portions other than the portion where the contact hole is formed above the peripheral circuit element.

6. A method for producing a solid-state imaging device according to claim 5, wherein:
the element-forming process forms as the peripheral circuit element a semiconductor element forming a comparator that compares an analog signal output from the image sensing element with a reference signal; and,
in the first-insulation-film forming step, the first insulation film is formed to cover a portion where the contact hole is to be formed above the semiconductor element forming a comparator, with portions other than the portion where the contact hole is to be formed above the peripheral circuit element being exposed.

7. A method for producing a solid-state imaging device according to claim 5 or 6, wherein:
the element-forming process forms as the peripheral circuit element a semiconductor element forming a digital-to-analog converter circuit that produces the reference signal; and,
in the first-insulation-film forming step, the first insulation film is formed to cover a portion where the contact hole is to be formed above the semiconductor element forming a digital-to-analog converter circuit, with portions other than the portion where the contact hole is to be formed above the peripheral circuit element being exposed.

8. A solid-state imaging device comprising:
a peripheral circuit element formed on a semiconductor substrate having an image sensing area where an image sensing element that captures an image of an object is provided and a peripheral area located on the periphery of the image sensing area, the peripheral circuit element being in the peripheral area;
a plurality of insulation films formed to cover at least the peripheral circuit element; and
a contact plug formed in a contact hole through the plurality of insulation films and above the peripheral circuit element in such a manner that the contact plug is electrically connected to the peripheral circuit element;
the plurality of insulation films including
a first insulation film, and
a second insulation film formed to cover the first insulation film,
the contact hole being formed by etching the second insulation film so as to remove a portion thereof where the contact hole is to be formed, and then etching the first insulation film so as to remove a portion thereof where the contact hole is to be formed,
the first insulation film being formed to serve as an etching stopper layer during etching of the second insulation film,
the first insulation film also being formed to cover a portion where the contact hole is to be formed above the peripheral circuit element, with portions other than the portion where the contact hole is to be formed above the peripheral circuit element being exposed.

9. An electronic apparatus comprising:
a peripheral circuit element formed on a semiconductor substrate having an image sensing area where an image sensing element that captures an image of an object is provided and a peripheral area located on the periphery of the image sensing area, the peripheral circuit element being in the peripheral area;
a plurality of insulation films formed to cover at least the peripheral circuit element; and
a contact plug formed in a contact hole through the plurality of insulation films and above the peripheral circuit element in such a manner that the contact plug is electrically connected to the peripheral circuit element;
the plurality of insulation films including
a first insulation film, and
a second insulation film formed to cover the first insulation film,
the contact hole being formed by etching the second insulation film so as to remove a portion thereof where the contact hole is to be formed, and then etching the first insulation film so as to remove a portion thereof where the contact hole is to be formed,
the first insulation film being formed to serve as an etching stopper layer during etching of the second insulation film,
the first insulation film also being formed to cover a portion where the contact hole is to be formed above the peripheral circuit element, with portions other than the portion where the contact hole is to be formed above the peripheral circuit element being exposed.
